(19) United States
(12) Patent Application Publication
(10) Pub. No.: US 2015/0194501 A1
(43) Pub. Date: Jul. 9, 2015

(54) METHOD FOR MANUFACTURING SEMICONDUCTOR DEVICE

(71) Applicants: Haizhou Yin, Poughkeepsie, NY (US); Keke Zhang, Liaocheng (CN)

(72) Inventors: Haizhou Yin, Poughkeepsie, NY (US); Keke Zhang, Liaocheng (CN)

(73) Assignee: Institute of Microelectronics, Chinese Academy of Sciences, Beijing (CN)

(21) Appl. No.: 14/413,616

(22) PCT Filed: Aug. 3, 2012
(86) PCT No.: PCT/CN2012/079692

§ 371 Date: Jan. 8, 2015

(30) Foreign Application Priority Data
Jul. 11, 2012 (CN) 201210240530.4

(51) Int. Cl. H01L 29/66

(52) U.S. Cl. CPC H01L 29/6659; H01L 29/66492; H01L 29/66545; H01L 29/665

(57) ABSTRACT

A method for manufacturing a semiconductor device, comprising: forming a gate stack structure and gate spacers on the substrate; forming the raised S/D regions on the substrate on both sides of the gate stack structure and the gate spacers; depositing a lower interlayer dielectric layer on the entire device, and planarizing the lower interlayer dielectric layer and the gate stack structure until the raised S/D regions are exposed; selective epitaxial growing to form the S/D extension regions in the raised S/D regions; forming an upper interlayer dielectric layer on the S/D extension regions; etching the upper interlayer dielectric layer until the S/D extension regions to form an S/D contact hole; forming a metal silicide in the S/D contact hole.

### CROSS-REFERENCE TO RELATED APPLICATION

This application claims priority to the Chinese Patent Application No. 201210240530.4, filed on Jul. 11, 2012, entitled “Method for Manufacturing Semiconductor Device”, which is incorporated herein by reference in its entirety.

### TECHNICAL FIELD

The present disclosure relates to the field of semiconductor integrated circuit manufacturing, and in particular, to a method of reducing the parasitic resistance in the raised Source/Drain (S/D).

### BACKGROUND

With the continuous development of integrated circuit processes, and particularly with the continuous proportional scaling-down of the device size, the parasitic effects in conventional MOSFET become more and more prominent. For example, for a long channel, the S/D parasitic resistance is much less than the channel region resistance and can be omitted. However, with the proportional scaling-down of the device, the intrinsic resistance of the channel region decreases, and the S/D region resistance, in particular, the contact resistance, increases rapidly with the size reduction, which makes the equivalent operating voltage decrease.

In order to reduce the S/D resistance, in prior art, the contact resistance between the S/D contact plug and the S/D regions is reduced by forming a metal silicide in the S/D regions, particularly in the S/D contact hole connecting the S/D regions. However, with the continuous scaling-down of the device size, the contact areas between the metal silicide and the S/D regions and between the metal silicide and the S/D contact plug are reduced accordingly. This conventional contact structure cannot sufficiently cancel out the increase in the parasitic resistance caused by size scaling-down with the use of low resistance metal silicide. Therefore, the device performance is still degraded.

### SUMMARY OF THE DISCLOSURE

For this reason, the purpose of the present disclosure is to reduce the parasitic resistance in the raised S/D, which effectively improves the semiconductor device performance.

The purpose of the present disclosure is realized by providing a method for manufacturing a semiconductor device, which comprises: forming a gate stack structure and gate spacers on the substrate; forming raised S/D regions on the substrate on both sides of the gate stack structure and the gate spacers; depositing a lower interlayer dielectric layer on the entire device, and planarizing the lower interlayer dielectric layer and the gate stack structure until the raised S/D regions are exposed; forming the S/D extension regions in the raised S/D regions by selective epitaxial growth; forming an upper interlayer dielectric layer on the S/D extension regions; etching the upper interlayer dielectric layer until the S/D extension regions to form S/D contact holes; and forming metal silicide in the S/D contact holes.

The method further comprises forming lightly doped S/D regions on the substrate on both sides of the gate stack structure before the gate spacers are formed.

The method further comprises forming the halo S/D doped regions on both sides of the channel region of the substrate before or after the gate spacers are formed.

The gate stack structure is a dummy gate stack structure comprising a gate dielectric layer and a gate filling layer.

The gate filling layer is poly-crystalline silicon, amorphous silicon, silicon oxide, or combinations thereof.

The step of planarizing the lower interlayer dielectric layer and the gate stack structure further comprises: planarizing the lower interlayer dielectric layer and the dummy gate stack structure until the gate filling layer is exposed; removing the gate filling layer to form a gate trench; forming a work function adjusting layer and a resistance adjusting layer on the lower interlayer dielectric layer and in the gate trench; and planarizing the lower interlayer dielectric layer, the work function adjusting layer, and the resistance adjusting layer until the raised S/D regions are exposed.

The gate dielectric layer is further removed after removal of the gate filling layer, and a gate oxide layer of high-k materials is formed in the gate trench before the formation of the work function adjusting layer.

The width of the S/D extension regions is greater than the width of the raised S/D regions.

The temperature for the selective epitaxial growth is lower than 700V.

In-situ doping is performing at the same time when the S/D extension regions are formed. Alternatively, implantation doping and annealing activation are performing after the S/D extension regions are formed.

The S/D extension regions and/or the raised S/D regions comprise Si, SiGe, Si:C, and combinations thereof.

Part of the S/D extension regions are removed when the S/D contact holes are formed by etching.

The step of forming the metal silicide further comprises: forming a metal layer in the S/D contact hole; annealing to make the metal layer react with the S/D extension regions to form the metal silicide; and removing the metal silicide of the unreacted metal layer.

The metal layer comprises Ni, Pt, Co, Ti, or combinations thereof.

According to the method for manufacturing a semiconductor device in the present disclosure, by epitaxially forming the raised S/D extension regions higher than the gate stack structure based on the conventional raised S/D, the volume of the S/D regions is increased, therefore reducing the parasitic resistance, and the device performance is effectively improved.

### BRIEF DESCRIPTION OF THE DRAWINGS

The technical solutions of the present disclosure will be described in more details below with reference to the accompanying drawings, wherein:

FIG. 1 is a schematic flow chart showing the method for manufacturing a semiconductor device according to the present disclosure; and

FIGS. 2-10 are schematic cross-sectional views of various steps of manufacturing a semiconductor device according to the present disclosure.

### DETAILED DESCRIPTION

Exemplary embodiments of the present disclosure will be described in more details below with reference to the accompanying drawings, to illustrate the features and effects of the technical solutions of the present disclosure. It should be noted that similar reference numerals denote similar structures in the drawings. The terms “first”, “second”, “above”, “below”, “thick”, “thin”, etc. can be used to denote all device structures. The description does not imply the space, order, or hierarchical relationship between the described device structures or process steps unless otherwise indicated.

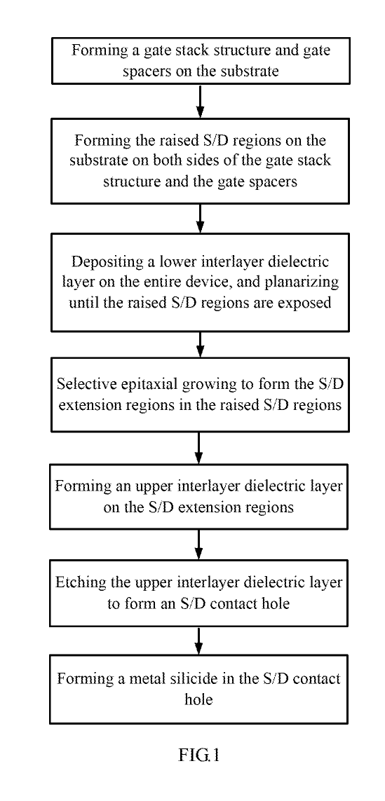

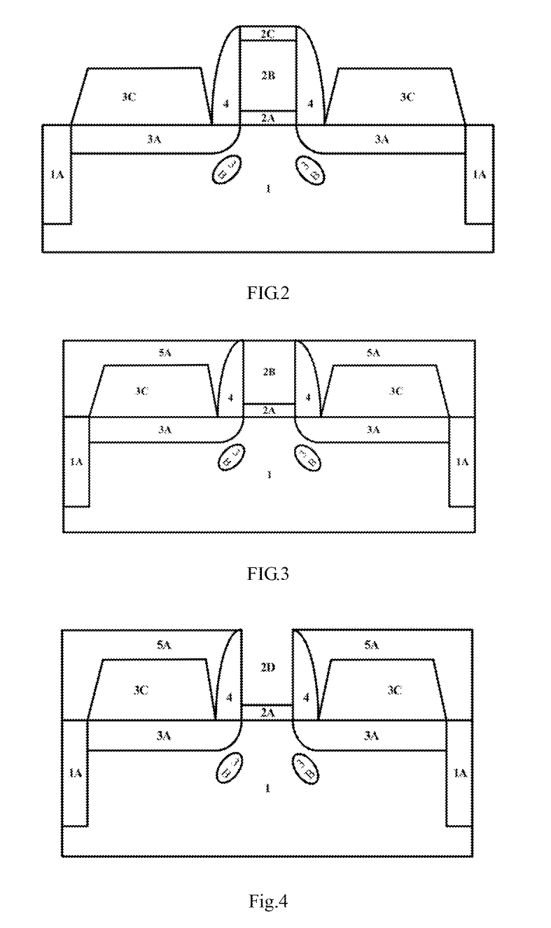

Referring to FIG. 1 and FIG. 2, a gate stack structure and gate spacers are formed on the substrate, and then the raised S/D regions are formed on the substrate on both sides of the gate stack structure and the gate spacers.

The substrate 1 is provided, the materials of which can be (bulk) silicon (for example, single crystal silicon wafer), SOI, GeOI (Ge on insulator), or other compound semiconductor, such as GaAs, SiGe, GeSn, InP, InSb, GaN, etc. Preferably, the substrate 1 may be made of bulk silicon or SOI so as to be compatible with the CMOS process. Preferably, the substrate 1 is etched to form a shallow trench, and insulator materials such as silicon oxide are deposited and filled into the trench to form a shallow trench isolation (STI) 1A. Substrate 1 surrounded by STI 1A constitutes the device active region.

A gate dielectric layer 2A and a gate filling layer 2B are sequentially formed in the active region by depositing and subsequently etching using conventional deposition methods such as LPCVD, PECVD, HDPCVD, MOCVD, MBE, ALD, evaporation, sputtering, etc. Preferably, a gate cap layer 2C (also called an etching stop layer), comprising materials of silicon nitride or silicon oxynitride, is formed on the top of the gate stack structure 2. When the gate stack structure is formed by the gate last process, i.e., a dummy gate stack structure is employed, the dummy gate dielectric layer 2A is a pad oxide layer of silicon oxide and the dummy gate filling layer 2B is poly-crystalline silicon, amorphous silicon, or even silicon oxide. In subsequent processes, a gate trench is formed by etching to remove the dummy gate stack structure, and a gate dielectric layer of high-k materials and a gate filling layer of metal materials are filled sequentially in the gate trench, wherein the gate dielectric layer surrounds the bottom and side surfaces (not shown) of the gate filling layer. The gate dielectric layer 2A is made of high-k materials comprising, but not limited to, nitrides (such as SiN, AlN, TiN), metal oxides (mainly oxides of the sub-group and lanthanide metal elements, such as Al₂O₃, Ta₂O₅, TiO₂, ZnO, ZrO₂, HfO₂, CeO₂, Y₂O₃, La₂O₃), perovskite oxides (such as PbZrₓTi₁₋ₓO₃ (PZT), BaₓSr₁₋ₓ, TiO₃ (BST)). The gate filling layer 2B is composed of metals, metal nitrides, and combinations thereof, wherein the metals comprising Al, Ti, Cu, Mo, W or Ta are used as the gate filling layer (resistance adjusting layer), and the metal nitrides comprising TiN, TaN are used as the work function adjusting layer. Note that although the exemplary embodiment in the present disclosure is targeted to the gate last process, i.e., the gate stack structure in FIG. 2 is a dummy gate stack structure, the gate first process can also be used in the present disclosure. The gate stack structure and types of the filling metal in the gate first process differ from those in the gate last process, and will not be described in detail herein since the current mainstream process is the gate last process.

Optionally, the first S/D implantation is performed to symmetrically implant impurities such as B, P, Ga, Al, N, and combinations thereof with lower energy and dose into the substrate 1 on both sides of the gate stack structure 2 consisting of the gate dielectric layer 2A and the gate filling layer 2B, to form lightly doped S/D regions, i.e. the S/D extension regions 3A (these lightly doped S/D regions, i.e. S/D extension regions, constitute LDD structure, which can suppress the hot electron effect). The implantation dose and energy can be determined according to the junction depth and the requirements for conductivity type and impurity concentration. For example, the implantation dose can be 1E11-1E13 cm⁻², and the implantation energy can be 2KeV-20KeV. Preferably, the implanted impurity can be activated by annealing.

The gate spacers 4 of materials comprising silicon nitride, silicon oxide, silicon oxynitride, diamond-like amorphous carbon (DLC), and combinations thereof are formed by etching after deposition on both sides of the gate stack structure 2 consisting of the gate dielectric layer 2A, the gate filling layer 2B, and the gate cap layer 2C. As illustrated in FIG. 2, the gate spacers 4 are formed higher than the gate filling layer 2B, i.e., the gate spacers can be alternatively integrated with the gate cap layer of the same materials. However, alternatively, the top of the gate spacers 4 can be aligned with the top of the gate filling layer 2B, i.e., the insulation dielectric 2C such as silicon nitride may not be formed on top of the gate filling layer 2B.

Alternatively, before or after the gate spacers 4 are formed, angled ion implantation is performing to implant the impurities of B, P, Ga, Al, N, etc. and the combinations thereof into the position below the lightly doped S/D regions 3A, approximately aligned with the gate spacers 4, i.e., the halo S/D doped regions 3B are formed close to the boundary between the lightly doped S/D regions 3A and the channel region (on both sides of the channel region). The implantation dose can be, such as, 5E12-5E13 cm².

The raised S/D regions 3C are formed on the gate stack structure 2/the substrate 1 on both sides of the gate spacer 4/the lightly doped S/D regions 3A by conventional epitaxial deposition methods such as MBE, MOCVD, ALD, PECVD, etc. The materials for the raised S/D regions 3C comprise Si, SiGe, Si:C, or combinations thereof to increase the stress and improve the carrier mobility in the channel region. Usually, the height of the raised S/D regions 3C is less than the height of the gate stack structure 2. Preferably, at the same time of epitaxial growth, in-situ doping can be performed so that the raised S/D regions 3C have the same conductivity type as the S/D extension regions 3A. Alternatively, after the epitaxial growth of the raised S/D regions 3C, doping ion implantation can be performing and subsequently the impurities can be activated by annealing, or after the growth of the S/D epitaxial regions 3D, dopant implantation can be performed together with the S/D epitaxial regions, so that the raised S/D regions 3C have the same conductivity type as the S/D extension regions 3A.

Referring to FIG. 1 and FIGS. 3-6, an (lower) interlayer dielectric layer (ILD) 5A is deposited on the entire device, and ILD 5 is planarized until the raised S/D regions 3C are exposed.

For the gate first process that is not shown in the Figures, the dummy gate stack structure may not be removed and the final gate stack structure may not be deposited. Therefore, the lower ILD 5 can be deposited directly and planarized by CMP until the raised S/D regions 3C are exposed. The various steps of the gate last process will be described below with reference to FIGS. 3-6 according to one exemplary embodiment of the present disclosure.

Referring to FIG. 3, an ILD 5 is deposited on the entire device and planarized until the gate stack structure 2 is exposed. The lower ILD 5A is formed by deposition on the STI 1A, the raised S/D regions 3C, the gate spacers 4 and the gate stack structure 2 by conventional methods such as LPCVD, PECVD, HDPCVD, spin coating, screen printing, spraying, etc. The lower ILD 5A is usually of low-k materials such as organic low-k materials (such as organic polymers containing aryl or polycyclic), inorganic low-k materials (such as amorphous carbon nitride films, polycrystalline boron nitride films, fluorinated silicate glass, BSG, PSG, BPSG), porous low-k materials (such as silsesquioxane (SSQ)-based porous low-k materials, porous silicon dioxide, porous SiOCH, C-doped silicon dioxide, F-doped porous amorphous carbon, porous diamond, porous organic polymers). Subsequently, the lower ILD 5A is planarized by methods such as CMP, etching back etc. until the dummy gate filling layer 2B in the dummy gate stack structure is exposed.

Referring to FIG. 4, the dummy gate filling layer 2B is removed by etching to form a gate trench 2D. Depending on the materials of the dummy gate filling layer 2B, TMAH or KOH can be used to remove the layer 2B of polycrystalline silicon and amorphous silicon by wet etching, HF can be used to etch the layer 2B of silicon oxide by wet etching, or dry etching can be used to etch the 2B layer. When the gate dielectric layer 2A is of high-k materials, the layer 2A can be retained in the gate trench 2C. When the gate dielectric layer 2A is only of common silicon oxide and is used as a pad oxide layer, the layer 2A can also be removed by etching preferably.

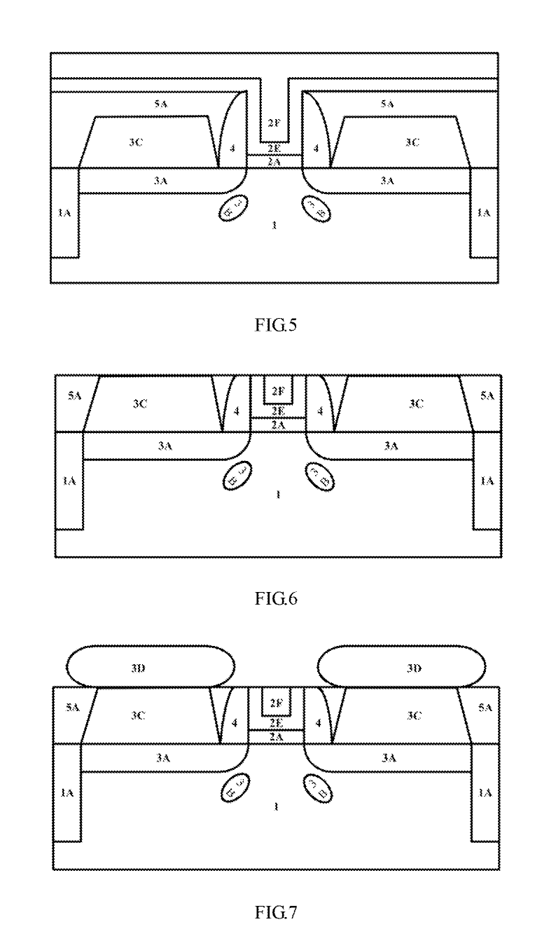

Referring to FIG. 5, a work function adjusting layer 2E and a resistance adjusting layer 2F can be sequentially deposited on the lower ILD 5A and in the gate trench 2D by conventional methods of PECVD, MOCVD, evaporation, sputtering, etc. The layer 2E can be of metal nitrides such as TiN, TaN, and the layer 2F can be of Cu, Al, W, Mo, Ti, and combinations thereof. The gate trench 2D is filled up by the layers 2E and 2F, and the layer 2E surrounds the bottom and side surfaces of the layer 2F. If the conventional gate dielectric layer 2A of silicon oxide is removed in the step shown in FIG. 4, a gate oxide layer of high-k materials can be deposited in the gate trench 2D before the layer 2E is deposited, and may be denoted by the same reference number as the previous gate dielectric layer 2A. Finally, the layers 2A, 2E, and 2F constitute the final gate stack structure 2.

Referring to FIG. 6, the layers 2F, 2E, and ILD 5A are planarized until the raised S/D regions 3C are exposed, by methods such as CMP and back etching, Note that when the gate first process is used, the steps in FIGS. 4 and 5 can be omitted and the structure in FIG. 6 can be obtained directly by CMP based on the structure in FIG. 3 (wherein the layers in the gate stack structure are stacked horizontally, and are not surrounded as shown in FIG. 6).

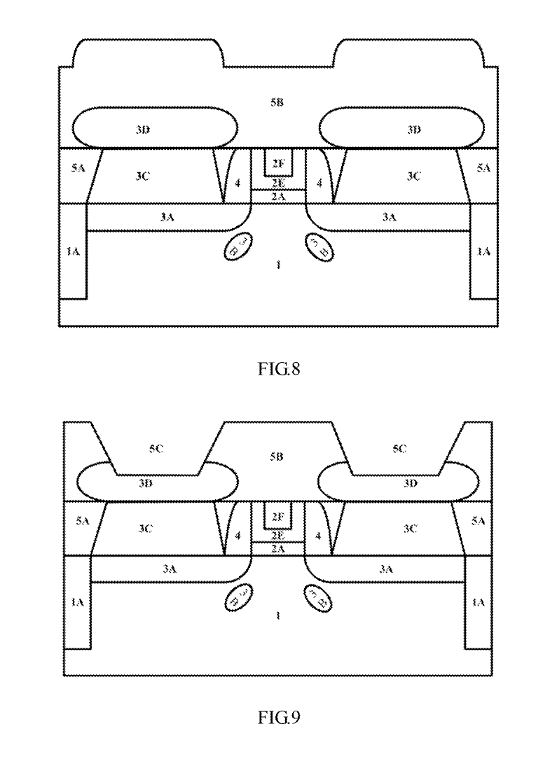

Referring to FIGS. 1 and 7, the S/D extension regions 3D are formed on the raised S/D regions 3C. The S/D extension regions 3D are formed by epitaxial growth on the exposed raised S/D regions 3C by conventional epitaxial methods such as PECVD, MBE, MOCVD, ALD, etc. Since the materials of the ILD 5A, the gate spacers 4, and the gate stack structure 2 are of different materials from the materials for the raised S/D regions 3C, the epitaxy only occurs on the raised S/D regions 3C and is called selective epitaxy. The epitaxial growth temperature is preferably lower than 700° C. to avoid the increase of defects in the gate dielectric layer 2A of high-k materials in the gate stack structure. The materials for the S/D extension regions 3D are preferably of the same materials as the raised epitaxial regions 3C, such as Si, SiGe, Si:C, etc. In addition, a thin buffer layer (not shown) can be formed first and a heteroepitaxial layer can be formed later. For example, a layer 3D of SiG/SiC can be epitaxially grown on a layer 3C of Si, or a layer 3D of Si can be epitaxially grown on a layer 3C of SiGe. As shown in FIG. 7, the width of the S/D epitaxial regions 3D is greater than the raised S/D regions 3C (preferably, the width of regions 3D is 1.1-2.0 times the width of regions 3C), and the top surface of the S/D epitaxial regions 3D is higher than the top surface of the gate stack structure 2 (preferably, the depth of regions 3D is 0.5-1.0 times the depth of regions 3C, and the depth of regions 3D is the height difference between the top surfaces), i.e., the new raised S/D regions constituted by the S/D epitaxial regions 3D and the raised S/D regions 3C are substantially T-typed. This T-typed configuration may increase the surface area of the S/D regions and the contact area, and may decrease the contact resistance. Preferably, in-situ doping is performed at the same time when the S/D epitaxial regions 3D are formed, or implantation doping is performed after the S/D epitaxial regions 3D are formed and activated by annealing, so that the S/D epitaxial regions 3D and the raised S/D regions 3C (and the S/D extension regions 3A, the halo S/D doping regions 3B) may have the same conductivity type. The doping concentration of the S/D epitaxial regions 3D and the raised S/D regions 3C is greater than the lightly doped S/D regions 3A. For example, the implantation dose can be 1E12-1E14 cm⁻².

Referring to FIGS. 1 and 8, an upper ILD 5B is formed on the entire device. The upper ILD 5B with the same or similar materials as the lower ILD 5A (which may be selected from the above mentioned materials for ILD 5A) is formed by conventional methods such as LPCVD, PECVD, HDPCVD, spin coating, screen printing, sputtering, etc.

Referring to FIGS. 1 and 9, the upper ILD 5B is etched to reach the S/D epitaxial regions 3D to form an S/D contact hole 5C. Depending on the materials for ILD 5B, such as silicon oxides, etc. the contact hole 5C is formed by dry etching (such as plasma etching) or wet etching (such as etchants of HF). Preferably, slightly over etching is achieved in the dry etching process to further etch part of the top surface of the S/D epitaxial regions 3D, so as to increase the subsequent contact area between the metal silicide and the S/D epitaxial regions 3D. The depth of over etching can be 1-5 nm, for example. In addition, the ILD 5B can be first etched, and subsequently the S/D epitaxial regions 3D can be etched by an additional etching process to reach the above mentioned depth range of 1-5 nm.

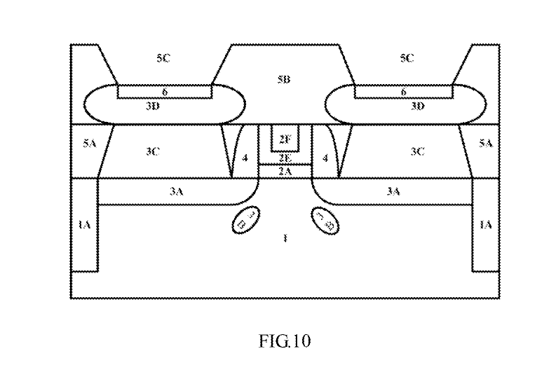

Referring to FIGS. 1 and 10, a metal silicide 6 is formed in the S/D contact hole 5C. For example, a thin metal layer comprising Ni, Pt, Co, Ti, and combinations thereof, is first deposited in the S/D contact hole 5C as precursor. The metal silicide 6 with low resistance is formed by thin metal layer reacting with Si in the S/D epitaxial regions at 450˜650° C., to further reduce the contact resistance. Subsequently, the unreacted thin metal layer is removed, and a layer of the metal silicide 6 is formed on the bottom of the S/D contact hole 5C (to be in contact with the S/D epitaxial regions 3D or reach into the S/D epitaxial regions 3D by a certain depth).

Hereafter, subsequent processes can be performing. For example, a blocking layer sequentially depositing materials of TiN, TaN in the S/D contact hole 5C and an S/D contact plug of metals such as Cu, Ti, Al, Mo, W, etc. can be formed (not shown).

According to the method for manufacturing the semiconductor device in the present disclosure, by epitaxially forming the raised S/D extension regions higher than the gate stack structure based on the conventional raised S/D, the volume of the S/D regions is increased to reduce the parasitic resistance, and the device performance is effectively improved.

Although the invention has been already illustrated according to the above one or more examples, it will be appreciated that numerous modifications and embodiments may be devised by people skilled in the art without deviating from the scope of the invention. Furthermore, it may be devised from the teachings of the disclosure changes suitable for special situation or materials without deviating the scope of the invention. Therefore, objects of the disclosure are not limited to special examples for preferred embodiments, meanwhile structure of the device and manufacture method thereof cover all embodiments fall into the scope of the invention.

I/We claim:

1. A method for manufacturing a semiconductor device, comprising:
forming a gate stack structure and gate spacers on the substrate;
forming raised S/D regions on the substrate on both sides of the gate stack structure and the gate spacers;
depositing a lower interlayer dielectric layer on the entire device, and planarizing the lower interlayer dielectric layer and the gate stack structure until the raised S/D regions are exposed;
forming the S/D extension regions in the raised S/D regions by selective epitaxial growth;
forming an upper interlayer dielectric layer on the S/D extension regions;
etching the upper interlayer dielectric layer until the S/D extension regions to form an S/D contact hole; and
forming a metal silicide in the S/D contact hole.

2. The method for manufacturing a semiconductor device according to claim 1, wherein before the gate spacers are formed, the method further comprises: forming lightly doped S/D regions on the substrate on both sides of the gate stack structure.

3. The method for manufacturing a semiconductor device according to claim 1, wherein before or after the gate spacers are formed, the method further comprises: forming halo S/D doped regions on both sides of the channel region in the substrate.

4. The method for manufacturing a semiconductor device according to claim 1, wherein the gate stack structure is a dummy gate stack structure comprising a gate dielectric layer and a gate filling layer.

5. The method for manufacturing a semiconductor device according to claim 4, wherein the gate filling layer is poly-crystalline silicon, amorphous silicon, silicon oxide, or combinations thereof.

6. The method for manufacturing a semiconductor device according to claim 4, wherein the step of planarizing the lower interlayer dielectric layer and the gate stack structure further comprises:
planarizing the lower interlayer dielectric layer and the dummy gate stack structure until the gate filling layer is exposed;
removing the gate filling layer to form a gate trench;
forming a work function adjusting layer and a resistance adjusting layer on the lower interlayer dielectric layer and in the gate trench; and
planarizing the lower interlayer dielectric layer, the work function adjusting layer, and the resistance adjusting layer until the raised S/D regions are exposed.

7. The method for manufacturing a semiconductor device according to claim 6, wherein the gate dielectric layer is further removed after the gate filling layer is removed, and a gate oxide layer of high-k materials is formed before the work function adjusting layer is formed.

8. The method for manufacturing a semiconductor device according to claim 1, wherein the width of the S/D extension regions is greater than the width of the raised S/D regions.

9. The method for manufacturing a semiconductor device according to claim 1, wherein the temperature for the selective epitaxial growth is lower than 700° C.

10. The method for manufacturing a semiconductor device according to claim 1, wherein in-situ doping is performing at the same time when the S/D extension regions are formed, or implantation doping and annealing activation are performing after the S/D extension regions are formed.

11. The method for manufacturing a semiconductor device according to claim 1, wherein the S/D extension regions and/or the raised regions comprise Si, SiGe, Si:C, and combinations thereof.

12. The method for manufacturing a semiconductor device according to claim 1, wherein part of the S/D extension regions are removed by etching when the S/D contact hole is formed by etching.

13. The method for manufacturing a semiconductor device according to claim 1, wherein the step of forming the metal silicide further comprise:
forming a metal layer in the S/D contact hole;
annealing so that the metal layer reacts with the S/D extension regions to form a metal silicide; and
removing the unreacted metal layer.

14. The method for manufacturing a semiconductor device according to claim 13, wherein the metal layer comprises Ni, Pt, Co, Ti, and combinations thereof.
